(19) United States
(12) Patent Application Publication
(10) Pub. No.: US 2026/0293005 A1
(43) Pub. Date: Sep. 24, 2026

(54) DISPLAY MODULE AND DISPLAY DEVICE

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Xiaolin Liu, Beijing (CN); Xinqi Lin, Beijing (CN); Hong Zhu, Beijing (CN)

(73) Assignees: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(21) Appl. No.: 19/476,493

(22) PCT Filed: Sep. 24, 2024
(86) PCT No.: PCT/CN2024/120590

§ 371 Date: Oct. 17, 2025

(30) Foreign Application Priority Data
Oct. 25, 2023 (CN) 202311398135.3

(51) Int. Cl. H05K 5/02

(52) U.S. Cl. CPC H05K 5/0217

(57) ABSTRACT

Provided is a display module, including a fixed middle frame, a movable front housing, a driving device, and a flexible display screen. A side of the fixed middle frame includes a guide groove; the movable front housing includes a guide tongue piece and is disposed on the side of the fixed middle frame with the guide groove; the flexible display screen includes a middle region and a scrolling region on a side thereof, the middle region is located on surfaces of the fixed middle frame and the movable front housing close to a display side, the scrolling region covers a surface of the movable front housing close to the display side and is bent to a surface of the movable front housing away from the display side. Strip-shaped members are arranged at intervals on a side of the scrolling region close to the movable front housing in the first direction.

### CROSS REFERENCE TO RELATED APPLICATION(S)

This application is a Section 371 National Stage Application of International Application No. PCT/CN2024/120590 filed on Sep. 24, 2024, which claims priority of Chinese Application No. 202311398135.3 filed on Oct. 25, 2023, the whole contents of which are incorporated herein by reference in their entireties.

### TECHNICAL FIELD

The present disclosure relates to the field of display technologies, and in particular to a display module and a display device.

### BACKGROUND

The application of flexible display devices is increasingly favored by the market, and a flexible-screen mobile phone is one of commonly used flexible display devices. The flexible-screen mobile phone refers to a mobile phone equipped with a bendable screen and with good flexibility. Compared with a conventional screen, a flexible screen has obvious advantages, not only provide a user with a brand-new use effect, but also have a smaller size and a lower power consumption. At the same time, the screen is flexible, which may reduce a risk of screen breakage.

### SUMMARY

The object of the present disclosure is to provide a display module with a flexible dynamic movement and a display device.

A display module is provided, including: a fixed middle frame, a side of the fixed middle frame is provided with a guide groove; a movable front housing disposed on the side of the fixed middle frame provided with the guide groove, the movable front housing includes a guide tongue piece matching with the guide groove to restrict a movement of the movable front housing relative to the fixed middle frame in a first direction; a driving device configured to drive the movable front housing to move relative to the fixed middle frame in the first direction; a flexible display screen including a middle region and a scrolling region located on a side of the middle region, the middle region is located on surfaces of the fixed middle frame and the movable front housing close to a display side, and the scrolling region covers a surface of the movable front housing close to the display side and is bent to a surface of the movable front housing away from the display side. When the movable front housing moves relative to the fixed middle frame in the first direction, a state of the scrolling region switches between an unfolded state and a scrolled state; a plurality of strip-shaped members are arranged at intervals in the first direction on a side of the scrolling region close to the movable front housing; and the first direction is a length direction of the fixed middle frame.

Optionally, the guide groove is an elongated guide groove extending in the first direction; and the guide groove includes a hollowed-out region penetrating the guide groove in a second direction, and the second direction is a direction perpendicular to a display surface.

Optionally, the hollowed-out region is located on a side of the guide groove away from the movable front housing; and a projection area of the hollowed-out region in the second direction accounts for 0 to ¾ of a projection area of the guide groove in the second direction.

Optionally, a sidewall of the guide groove is provided with a sub-guide groove; the sub-guide groove matches with the guide tongue piece to prevent a movement of the movable front housing relative to the fixed middle frame in a second direction; and the second direction is a direction perpendicular to a display surface.

Optionally, a guide rail is provided on each of two sides of the fixed middle frame in the first direction, a guide slider is provided on the guide rail, and the guide slider is fixedly connected to the movable front housing.

Optionally, a plurality of support groups are provided on a side of the scrolling region close to the movable front housing; each of the plurality of support groups includes a plurality of supports arranged at intervals in the first direction; and the plurality of supports are configured to support the flexible display screen, such that a spacing is provided between the flexible display screen and the movable front housing.

Optionally, the plurality of support groups includes a first support group disposed on each of two opposite sides of the flexible display screen in a third direction; a rail slider is provided at an end of a support in each of the first support groups close to the movable front housing; and a U-shaped side rail is provided on each of two opposite sides of the movable front housing, a U-shaped opening of each side rail faces the fixed middle frame, and the rail slider is configured to slide along the side rail.

Optionally, the plurality of support groups further includes second support groups disposed between the two first support groups; a plurality of intermediate rails are provided between the side rails on two sides of the movable front housing, and the number of the plurality of intermediate rails corresponds to the number of the second support groups; and each of the plurality of intermediate rails is a U-shaped rail, a U-shaped opening of the intermediate rail faces the fixed middle frame, and the rail slider is configured to slide along the intermediate rail.

Optionally, the side rail includes an elongated first inner guide post and a U-shaped first outer guide post, the first outer guide post surrounds the first inner guide post, and a first U-shaped rail groove is formed between the first outer guide post and the first inner guide post.

Optionally, a front housing side cover is provided on each of two sides of the movable front housing; the first outer guide post is disposed on the front housing side cover; and the first inner guide post is jointly formed by a first protrusion located on the front housing side cover and a second protrusion located on each of two sides of the movable front housing.

Optionally, the intermediate rail includes an elongated second inner guide post and a U-shaped second outer guide post, the second outer guide post surrounds the second inner guide post, and a second U-shaped rail groove is formed between the second outer guide post and the second inner guide post.

Optionally, the second outer guide post located in a bending region of the second U-shaped rail groove is manufactured separately and then assembled to the movable front housing to form a closed intermediate rail.

Optionally, a distance between an intermediate rail and an adjacent side rail is less than or equal to 110 mm, and a distance between adjacent intermediate rails is less than or equal to 110 mm.

Optionally, the guide groove and the movable front housing are symmetrically provided on the other side of the fixed middle frame; and the scrolling region is symmetrically provided on the other side of the middle region.

Optionally, a front housing push rod is provided on each of two sides of the movable front housing in the first direction, and an end of the front housing push rod close to the fixed middle frame is fixed with the guide slider; the flexible display screen includes a circuit board region, and a projection of the circuit board region in the second direction falls between the front housing push rods on two sides of the movable front housing; an end of the front housing push rod close to the fixed middle frame is connected to a connector, and the connector is connected to the driving device; and the second direction is the direction perpendicular to the display surface.

A display device is further provided, including the display module described above.

It should be understood that the above-mentioned general descriptions and the following detailed descriptions are only exemplary and explanatory, and are not intended to limit the present disclosure.

### BRIEF DESCRIPTION OF THE DRAWINGS

The accompanying drawings here are incorporated into the specification and constitute a part of the specification, illustrating the embodiments consistent with the present disclosure, and are used to explain the principle of the present disclosure together with the specification.

FIG. 1 is an exploded structural diagram of a display module in an embodiment of the present disclosure.

FIG. 2 is a schematic structural diagram of a display module in an embodiment of the present disclosure.

FIG. 3 is a schematic partial structural diagram of a flexible display screen of a display module in an embodiment of the present disclosure.

FIG. 4 is a schematic partial top-view diagram of a display module in an embodiment of the present disclosure.

FIG. 5 is a schematic partial structural diagram of a display module in an embodiment of the present disclosure.

FIG. 6 is a top-view schematic diagram of a display module in an embodiment of the present disclosure.

FIG. 7 is a schematic structural diagram of a front housing push rod of a display module in an embodiment of the present disclosure.

FIG. 8 is a schematic structural diagram of a side rail of a display module in an embodiment of the present disclosure.

FIG. 9 is a schematic structural diagram of a front housing side cover of a display module in an embodiment of the present disclosure.

FIG. 10 is a schematic structural diagram of a side rail of a display module in an embodiment of the present disclosure.

FIG. 11 is a schematic partial structural diagram of a display module in an embodiment of the present disclosure.

FIG. 12 is a schematic structural diagram of an intermediate rail of a display module in an embodiment of the present disclosure.

FIG. 13 is a schematic structural diagram of an intermediate rail of a display module in an embodiment of the present disclosure.

FIG. 14 is a top-view schematic diagram of a display module in an embodiment of the present disclosure.

### DETAILED DESCRIPTION OF EMBODIMENTS

Here, exemplary embodiments will be described in detail, and examples of the exemplary embodiments are illustrated in the accompanying drawings. When the accompanying drawings are involved in the following descriptions, the same numerals in different accompanying drawings indicate the same or similar elements, unless otherwise indicated. The implementations described in the following exemplary embodiments do not represent all implementations consistent with the specification. On the contrary, they are merely examples of devices and methods consistent with some aspects of the specification as detailed in the appended claims.

Terms used in the present disclosure are only for the purpose of describing specific embodiments, and are not intended to limit the present disclosure. Unless otherwise defined, technical or scientific terms used in the specification shall have ordinary meanings as understood by those of ordinary skill in the art to which the present disclosure belongs. As used in the specification and the claims, terms “first”, “second” and similar terms do not indicate any order, quantity or importance, but are merely used to distinguish different components. Similarly, terms such as “a” or “an” also do not indicate any quantity limitation, but indicate presence. “Plurality” or “a number of” means two or more. Unless otherwise specified, terms such as “front”, “rear”, “lower” and/or “upper” are only for convenience of description and are not limited to one position or one spatial orientation. Terms such as “including” or “comprising” means that an element or item preceding “including” or “comprising” covers elements or items listed after “including” or “comprising” and their equivalents, but does not exclude other elements or items. Terms such as “connected” or “coupled” are not limited to a physical or mechanical connection, and may include an electrical connection, whether in a direct or indirect way.

The terms used in the specification are only for the purpose of describing specific embodiments, and are not intended to limit the present disclosure. As used in the specification and the appended claims, singular forms “a”, “an” and “the” are also intended to include plural forms, unless the context clearly indicates otherwise. It should also be understood that the term “and/or” as used herein refers to and includes any or all possible combinations of one or more associated listed items.

With the development of flexible display technologies, various forms of flexible display devices have emerged, such as a foldable display device, a sliding display device, a scrollable display device. As a brand-new flexible display device, the scrollable display device has a great application value. However, a dynamic movement of a related scrollable display device is not flexible enough.

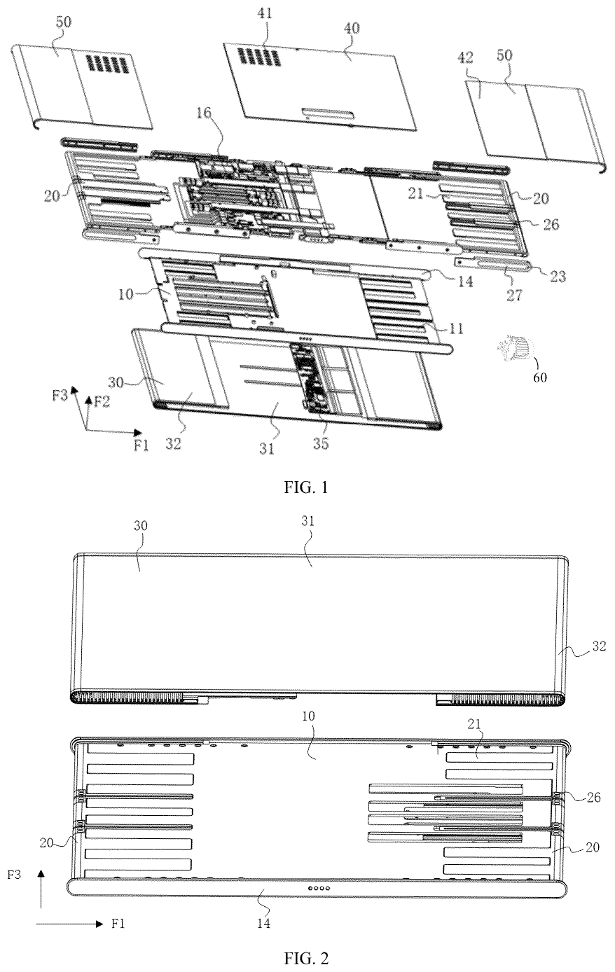

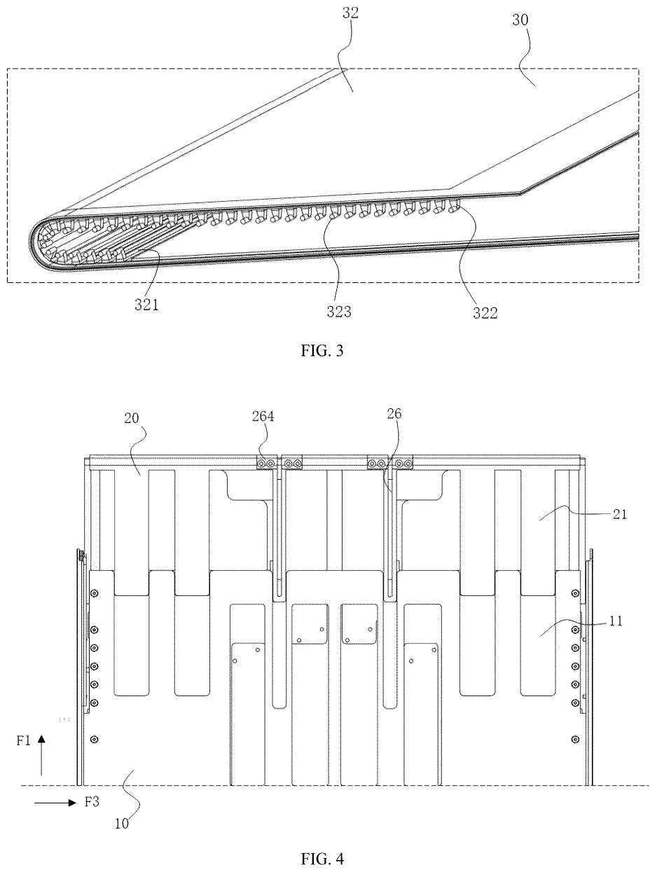

As shown in FIG. 1 and FIG. 3, a display module is provided in the present disclosure, including: a fixed middle frame 10, one side of the fixed middle frame 10 is provided with a guide groove 11; a movable front housing 20 disposed on the side of the fixed middle frame 10 provided with the guide groove 11, the movable front housing 20 includes a guide tongue piece 21 matching with the guide groove to restrict a movement of the movable front housing 20 relative to the fixed middle frame 10 in a first direction F1; a driving device 60 used to drive the movable front housing 20 to move relative to the fixed middle frame 10 in the first direction F1; a flexible display screen 30 including a middle region 31 and a scrolling region 32 located on a side of the middle region 31, the middle region 31 is located on surfaces of the fixed middle frame 10 and the movable front housing 20 close to a display side, and the scrolling region 32 covers a surface of the movable front housing 20 close to the display side and is bent to a surface of the movable front housing 20 away from the display side. When the movable front housing 20 moves relative to the fixed middle frame 10 in the first direction F1, a state of the scrolling region 32 switches between an unfolded state and a scrolled state; a plurality of strip-shaped members 321 are arranged at intervals in the first direction F1 on a side of the scrolling region 32 close to the movable front housing 20; and the first direction F1 is a length direction of the fixed middle frame 10.

A display device is further provided in the present disclosure, including the above-mentioned display module.

In the present disclosure, through the matching of the guide tongue piece with the guide groove as well as arrangements of the flexible display screen and the strip-shaped members, the display module may be flexibly scrolled and unfolded.

Embodiments of the present disclosure will be described in detail below.

In the present disclosure, the first direction F1 is the length direction of the fixed middle frame 10, a second direction F2 is a direction perpendicular to a display surface, and a third direction F3 is a width direction of the fixed middle frame 10.

As shown in FIG. 1 to FIG. 6, a display module is provided in the present disclosure. The display module includes a fixed middle frame 10, a movable front housing 20, a flexible display screen 30, a fixed rear housing 40, and a movable rear housing 50. For example, as shown in FIG. 1, the display module may include the fixed middle frame 10, the movable front housing 20, the flexible display screen 30, the fixed rear housing 40, and the movable rear housing 50.

The fixed middle frame 10 is provided with key components 16 of a whole display module. The key components 16 include, but are not limited to, a battery, a main board, a driver board, a speaker, an FPC assembly, etc. An arrangement of the key components 16 may be determined according to requirements, and the number of the key components 16 may also be determined according to requirements.

A plurality of guide grooves 11 are provided on a side of the fixed middle frame 10 in the second direction F2, and each guide groove 11 extends in the first direction F1. For example, as shown in FIG. 1, a guide groove 11 is formed by recessing from a side of the fixed middle frame 10 in the second direction F2 to the other side of the fixed middle frame 10 in the second direction F2. A bottom of the guide groove 11 is close to the flexible display screen 30, and an opening of the guide groove 11 is away from the flexible display screen 30. Middle frame side covers 14 are provided on two opposite sides of the fixed middle frame 10 in the third direction F3, and the middle frame side covers 14 cover the two opposite sides of the fixed middle frame 10 in the third direction F3.

The movable front housing 20 is disposed on a side of the fixed middle frame 10 provided with the guide groove 11, and the movable front housing 20 includes a plurality of guide tongue pieces 21. Each guide tongue piece 21 extends in the first direction F1, and a width of the guide tongue piece 21 in the third direction F3 is slightly less than a width of the guide groove 11 in the third direction F3. A length of the guide tongue piece 21 in the first direction F1 is slightly less than a length of the guide groove 11 in the first direction F1. Both the length and the width of the guide tongue piece 21 in the third direction F3 are slightly less than the length and the width of the guide groove 11, such that the guide tongue piece 21 may be correctly clamped in the guide groove 11 and may slide along the guide groove 11. The guide tongue piece 21 matches with the guide groove 11, such that the guide tongue piece 21 may slide along the guide groove 11 in the first direction F1 to restrict the movable front housing 20 to move in the first direction F1 relative to the fixed middle frame 10. The driving device 60 may be disposed on the fixed middle frame 10, the driving device is connected to the movable front housing 20, and the driving device drives the movable front housing 20 to move in the first direction F1 relative to the fixed middle frame 10. In an embodiment, the driving device 60 may be a motor.

As shown in FIG. 4, in an optional embodiment, the plurality of guide grooves 11 are arranged at intervals in the third direction F3 on a side of the fixed middle frame 10. The plurality of guide tongue pieces 21 are arranged at intervals in the third direction F3 on a side of the movable front housing 20 close to the fixed middle frame 10. The number of the guide tongue pieces 21 is the same as the number of the guide grooves 11.

As shown in FIG. 4 and FIG. 5, in an optional embodiment, the guide groove 11 is an elongated guide groove 11 extending in the first direction F1. The guide groove 11 includes a hollowed-out region 111. The hollowed-out region 111 may be acquired by: hollowing out a portion of the guide groove 11 in the second direction F2, such that the portion of the guide groove 11 is penetrated in the second direction F2. Partial hollowing-out is realized by providing the hollowed-out region 111 in the guide groove 11, which may reduce a jamming problem caused by deformation during processing of the fixed middle frame 10. When jamming occurs, a sliding resistance of the guide tongue piece 21 sliding along the guide groove 11 may increase, a wear between the guide tongue piece 21 and the guide groove 11 may also increase, and debris generated by the wear may cause a risk of short circuit of a circuit board, etc. The partial hollowing-out is realized by providing the hollowed-out region 111 in the guide groove 11, which may also reduce an overlapping area between the guide tongue piece 21 and the guide groove 11 when the guide tongue piece 21 slides along the guide groove 11, thereby reducing a friction between the guide tongue piece and the guide groove. The partial hollowing-out is realized by providing the hollowed-out region 111 in the guide groove 11, which may reduce an overall weight of the fixed middle frame 10, thereby realizing lightweight of the display module.

Optionally, the hollowed-out region 111 is located on a side of the guide groove 11 away from the movable front housing 20. For example, the hollowed-out region 111 is located on a side of the guide groove 11 away from the movable front housing 20 in the first direction F1. A projection area of the hollowed-out region 111 in the second direction F2 accounts for 0 to ¾ of a projection area of the guide groove 11 in the second direction F2. For example, the projection area of the hollowed-out region 111 in the second direction F2 may account for ⅕, ¼, ⅖, ½, or ¾ of the projection area of the guide groove 11 in the second direction F2. Optionally, the hollowed-out region 111 may be a square hollowed-out region 111, or may be a circular, elliptical, or irregularly shaped hollowed-out region 111.

After the partial hollowing-out is realized by proving the hollowed-out region 111 in the guide groove 11, a remaining portion is a platform region 112. The platform region 112 is located on a side of the guide groove 11 close to the movable front housing 20. For example, the platform region 112 is located on a side of the guide groove 11 close to the movable front housing 20 in the first direction F1. A portion of the platform region 112 is located in the opening of the guide groove 11, and the other portion of the platform region 112 extends from the opening of the guide groove 11 toward a side of the movable front housing 20. The platform region 112 provides a support for the guide tongue piece 21 of the movable front housing 20 in the second direction F2, which may prevent the guide tongue piece 21 from shifting in the second direction F2, thereby guiding the guide tongue piece 21 to be correctly inserted into the guide groove 11. The platform region 112 may also ensure a structural strength of the fixed middle frame 10 itself, such that the hollowed-out region 111 may not cause a loss of the structural strength of the fixed middle frame 10 itself.

As shown in FIG. 4 and FIG. 5, in an optional embodiment, a sidewall of the guide groove 11 is provided with a sub-guide groove 113. The sub-guide groove 113 is formed by inwardly recessing the sidewall of the guide groove 11 in the third direction F3. The sub-guide groove 113 communicates with the sidewall of the guide groove 11 in the first direction F1. When the guide tongue piece 21 slides along the guide groove 11 in the first direction F1, a side edge of the guide tongue piece 21 may be clamped by the sub-guide groove 113, so as to prevent a movement of the guide tongue piece 21 relative to the guide groove 11 in the second direction F2, thereby preventing a movement of the movable front housing 20 relative to the fixed middle frame 10 in the second direction F2.

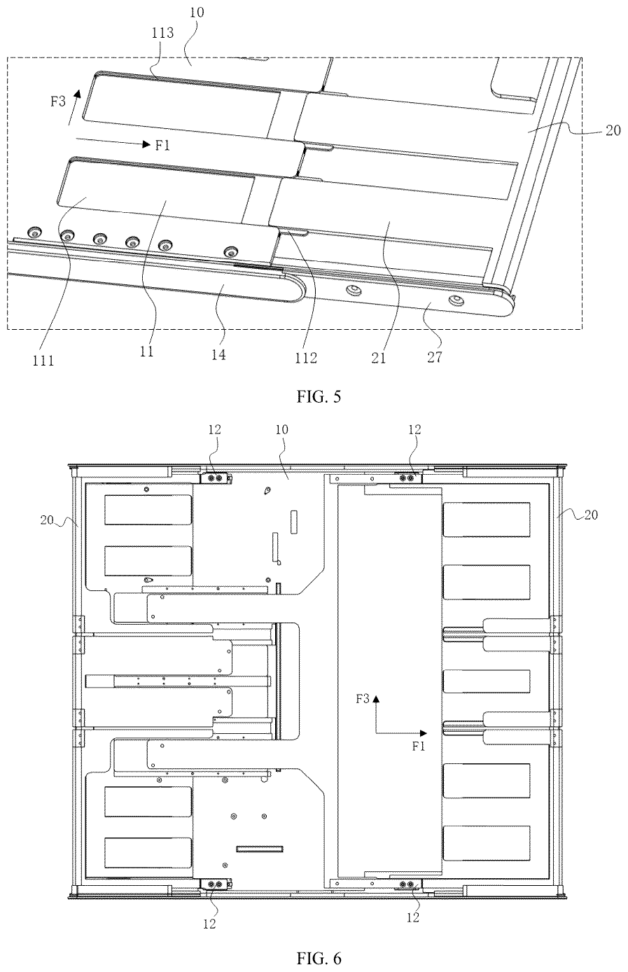

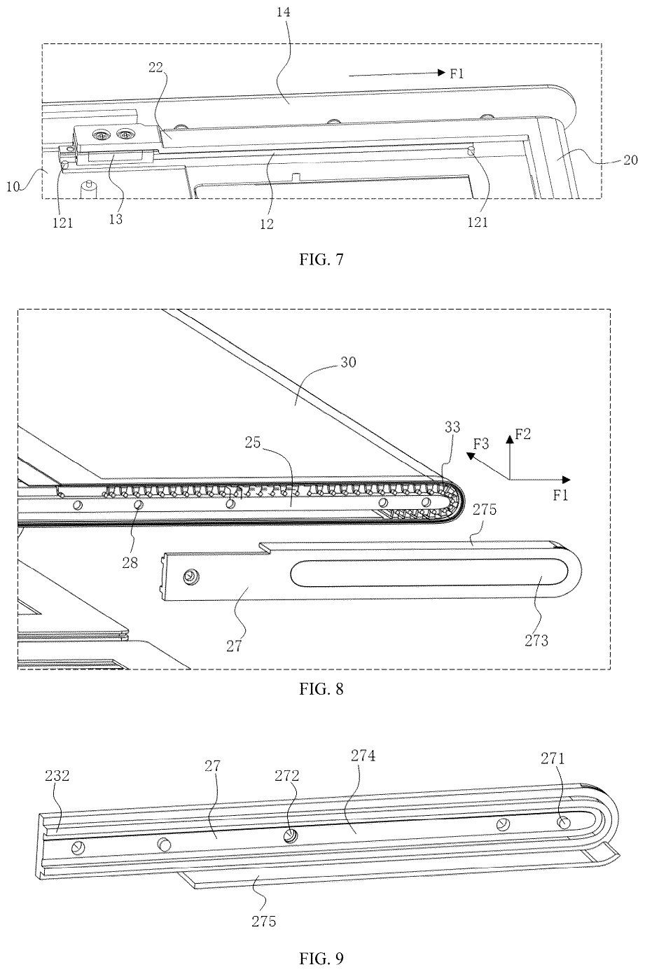

As shown in FIG. 6 to FIG. 7, in an optional embodiment, guide rails 12 are provided on two sides of the fixed middle frame 10 in the third direction F3. Each of the guide rails 12 extends in the first direction F1, and a guide slider 13 is provided on the guide rail 12. The guide slider 13 may slide on the guide rail 12 in the first direction F1 relative to the guide rail 12. The guide slider 13 may be fixedly connected to the movable front housing 20. Optionally, front housing push rods 22 are provided on two sides of the movable front housing 20 close to the fixed middle frame 10. Each of the front housing push rod 22 extends in the first direction F1, and an end of the front housing push rod 22 close to the fixed middle frame 10 is fixedly connected to the guide slider 13. The front housing push rod 22, the guide slider 13, and the guide rail 12 match with each other to further restrict the movement of the movable front housing 20 relative to the fixed middle frame 10 in the first direction F1. An arrangement of the guide rail 12 may also improve an assembly accuracy between the fixed middle frame 10 and the movable front housing 20, and reduce a friction of a relative displacement between the fixed middle frame 10 and the movable front housing 20. The guide rail 12 is provided with guide rail barriers 121 at minimum and maximum displacement positions of the relative displacement between the fixed middle frame 10 and the movable front housing 20. The guide rail barriers 121 may limit maximum and minimum values of the movement of the movable front housing 20 relative to the fixed middle frame 10, thereby preventing the movable front housing 20 from falling off and reducing a wear between the movable front housing 20 and the fixed middle frame 10. Optionally, the guide rail barriers 121 may be a columnar protrusion, an arc protrusion, or other structures that may block the guide slider 13.

The flexible display screen 30 covers surfaces of the fixed middle frame 10 and the movable front housing 20 close to a display side in the second direction F2. The flexible display screen 30 is bent at an end of the movable front housing 20 away from the fixed middle frame 10 in the first direction F1, and covers a surface of the movable front housing 20 away from the display side. The display side refers to an opposite direction of the second direction F2 shown in FIG. 1. The flexible display screen 30 includes the middle region 31 and the scrolling region 32 located on a side of the middle region. The middle region 31 is located on surfaces of the fixed middle frame 10 and the movable front housing 20 close to the display side, and the scrolling region 32 covers the surface of the movable front housing 20 close to the display side and is bent to the surface of the movable front housing 20 away from the display side. When the movable front housing 20 moves in the first direction F1 relative to the fixed middle frame 10, the state of the scrolling region 32 switches between the unfolded state and the scrolled state. When the movable front housing 20 moves in the first direction F1 to a position farthest from the fixed middle frame 10, the scrolling region 32 is unfolded, that is, most of the scrolling region 32 on the surface of the movable front housing 20 away from the display side is unfolded to the surface of the movable front housing 20 close to the display side, that is, the most of the scrolling region 32 and the middle region 31 together form an effective display surface. When the movable front housing 20 moves in the first direction F1 to a position closest to the fixed middle frame 10, the scrolling region 32 is scrolled, that is, most of the scrolling region 32 on the surface of the movable front housing 20 close to the display side is scrolled to the surface of the movable front housing 20 away from the display side, that is, the middle region 31 forms an effective display surface, while the scrolling region 32 does not form an effective display surface.

A side of the middle region 31 close to the movable front housing 20 is made of a rigid structural member. Optionally, the side of the middle region 31 close to the movable front housing 20 may be made of a stainless steel sheet, titanium alloy, carbon fiber, or the like. The middle region 31 and the fixed middle frame 10 are fixed by a dispensing or gluing method. Optionally, a buffer material or a heat dissipation material may be placed between the fixed middle frame 10 and the middle region 31, so as to enhance heat dissipation and impact resistance effects. Optionally, the buffer material may be a material with elastic deformation ability such as foam, silica gel, or rubber; and the heat dissipation material may be graphite, copper, or other materials with thermal conductivity. Only the buffer material, only the heat dissipation material, or a stacked combination of the buffer material and the heat dissipation material may be provided between the fixed middle frame 10 and the middle region 31, so as to realize both buffer and heat dissipation effects.

The plurality of strip-shaped members 321 are arranged at intervals in the first direction F1 on a side of the scrolling region 32 close to the movable front housing 20. The strip-shaped member 321 extends in the third direction F3, and the strip-shaped member 321 extends from a side of the scrolling region 32 to the other side of the scrolling region 32 in the third direction F3. The arrangement of the strip-shaped members 321 may allow the scrolling region 32 to be bent freely.

As shown in FIG. 3, in an optional embodiment, a plurality of support groups are provided on a side of the scrolling region 32 close to the movable front housing 20. Each support group includes a plurality of supports 322 arranged at intervals in the first direction F1. The supports 322 support the flexible display screen 30 to maintain a certain spacing between the flexible display screen 30 and the movable front housing 20, so as to prevent the flexible display screen 30 from being scratched. The spacing between the flexible display screen 30 and the movable front housing 20 may be adjusted by adjusting a height of the supports 322. Optionally, a support 322 may be disposed on a side of a strip-shaped member 321 close to the movable front housing 20. The number of supports 322 in each support group may be the same as or different from the number of strip-shaped members 321, and the supports 322 in one of the support groups are respectively disposed on a side of different strip-shaped members 321 close to the movable front housing 20.

As shown in FIG. 3, FIG. 8, FIG. 10, and FIG. 11, in an optional embodiment, the plurality of support groups include first support groups 33 disposed on two opposite sides of the flexible display screen 30 in the third direction F3. As shown in FIG. 3, rail sliders 323 is provided at ends of the supports 322 close to the movable front housing 20. U-shaped side rails 23 are provided on two opposite sides of the movable front housing 20, a U-shaped opening of the side rail 23 faces the fixed middle frame 10, and the rail sliders 323 may slide along the side rail 23. When the movable front housing 20 moves relative to the fixed middle frame 10 in the first direction F1, the rail sliders 323 may slide along the U-shaped side rail 23, such that the state of the scrolling region 32 of the flexible display screen 30 may switch between the unfolded state and the scrolled state. Optionally, the rail slider 323 may be in a shape of a cylinder, an elliptic cylinder, a circular truncated cone, or the like extending in the third direction F3, as long as its side is a smooth curve. In this way, the rail sliders 323 may slide smoothly inside the side rail 23.

As shown in FIG. 10, in an optional embodiment, the side rail 23 includes an elongated first inner guide post 231 and a U-shaped first outer guide post 232. The first inner guide post 231 extends in the first direction F1, and a U-shaped opening of the first outer guide post 232 faces the fixed middle frame 10 in the first direction F1. The first outer guide post 232 surrounds the first inner guide post 231, the first outer guide post 232 and the first inner guide post 231 are spaced, and a spacing between the first outer guide post 232 and the first inner guide post 231 forms a first U-shaped rail groove 233. The rail slider 323 may be clamped in the first U-shaped rail groove 233 and slide along the first U-shaped rail groove 233.

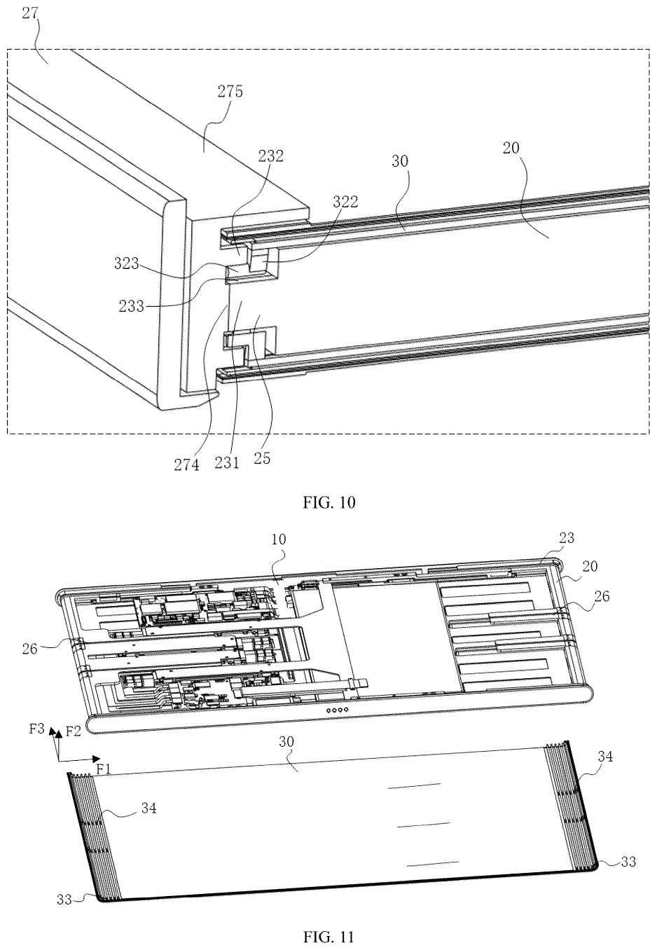

As shown in FIG. 5, and FIG. 8 to FIG. 10, in an optional embodiment, front housing side covers 27 are provided on two sides of the movable front housing 20. The first outer guide post 232 is disposed on the front housing side cover 27. The first inner guide post 231 is jointly formed by a first protrusion 274 located on the front housing side cover 27 and a second protrusion 25 located on two sides of the movable front housing 20. Optionally, a length of the first protrusion 274 and a length of the second protrusion 25 are adjustable, and when the length of the first protrusion 274 increases, the length of the second protrusion 25 decreases accordingly. In this embodiment, the length of the second protrusion 25 in the third direction F3 is approximately equal to a length of the rail slider 323 in the third direction F3, and a 15% error is allowed for the length of the second protrusion 25 in the third direction F3 and the length of the rail slider 323 in the third direction F3. The length of the second protrusion 25 in the third direction F3 is approximately equal to the length of the rail slider 323 in the third direction, such that the flexible display screen 30 may be pre-assembled to the movable front housing 20 more conveniently and accurately.

A side of the front housing side cover 27 is provided with a cover lapping plate 275, and the cover lapping plate 275 is used for positioning and lapping with the movable front housing 20. The front housing side cover 27 is pre-positioned with the movable front housing 20 by means of a positioning post 271, and is fixed to the movable front housing 20 by means of a screw 272. Screw holes and positioning holes 28 are provided on two sides of the movable front housing 20. Specifically, the screw holes and positioning holes 28 are disposed on the second protrusion 25. At least two positioning posts 271 are disposed on a side of the front housing side cover 27 close to the movable front housing 20 in the first direction F1. Specifically, the positioning post 271 may be disposed on the first protrusion 274. A plurality of screws 272 are disposed on the front housing side cover 27 in the first direction F1. A distance between adjacent screws 272 is approximately 20 mm. Optionally, the distance between adjacent screws 272 may be 17 mm, 18 mm, 19 mm, 20 mm, 21 mm, or the like. In a bending region of the flexible display screen 30, the distance between adjacent screws 272 may be set to be less.

An appearance trim strip 273 is provided on a side of the front housing side cover 27 away from the movable front housing 20. The appearance trim strip 273 is disposed in the first direction F1, and the appearance trim strip 273 covers the screws 272, so as to enhance a degree of aesthetics of the module. When the flexible display screen 30 is scrolled, that is, the movable front housing 20 is relatively close to the fixed middle frame 10, the front housing side cover 27 may be covered by the middle frame side cover 14 in the third direction F3. When the flexible display screen 30 is unfolded, that is, the movable front housing 20 is relatively away from the fixed middle frame 10, the front housing side cover 27 may not be covered by the middle frame side cover 14 in the third direction F3.

As shown in FIG. 11, in an optional embodiment, the plurality of support groups further include a plurality of second support groups 34 disposed between the two first support groups 33 on the two opposite sides of the flexible display screen 30 in the third direction F3. A plurality of intermediate rails 26 are provided between the side rails 23 on two sides of the movable front housing 20, and the number of the plurality of intermediate rails 26 corresponds to the number of the second support groups 34. The intermediate rail 26 is a U-shaped rail, and a U-shaped opening of the intermediate rail 26 faces the fixed middle frame 10.

The rail slider 323 is provided at an end of the support 322 close to the movable front housing 20, and the rail slider 323 may slide along the intermediate rail 26. Optionally, the rail slider 323 may be in a shape of a cylinder, an elliptic cylinder, or the like extending in the third direction F3. When the movable front housing 20 moves relative to the fixed middle frame 10 in the first direction F1, the rail slider 323 may slide along the U-shaped intermediate rail 26, such that the state of the scrolling region 32 of the flexible display screen 30 may switch between the unfolded state and the scrolled state.

The length of the guide tongue piece 21 and the length of the guide groove 11 in the first direction F1 are determined by a length of the scrolling region 32 when it is fully unfolded. For example, if the length of the scrolling region 32 is X when it is fully unfolded, the length of the guide tongue piece 21 and the length of the guide groove 11 in the first direction F1 are greater than X. Optionally, the length of the guide tongue piece 21 and the length of the guide groove 11 in the first direction F1 may be X+4 mm, X+5 mm, X+6 mm, X+7 mm, X+8 mm, or the like. This may ensure that when the scrolling region 32 is fully unfolded, a certain overlapping length is provided between the guide tongue piece 21 and the guide groove 11, such that a problem of jamming and retraction failure of the flexible display screen 30 during scrolling and unfolding due to the fixed middle frame 10 being disconnected from the movable front housing 20 caused by the guide tongue piece 21 being disconnected from the guide groove 11 may be avoided.

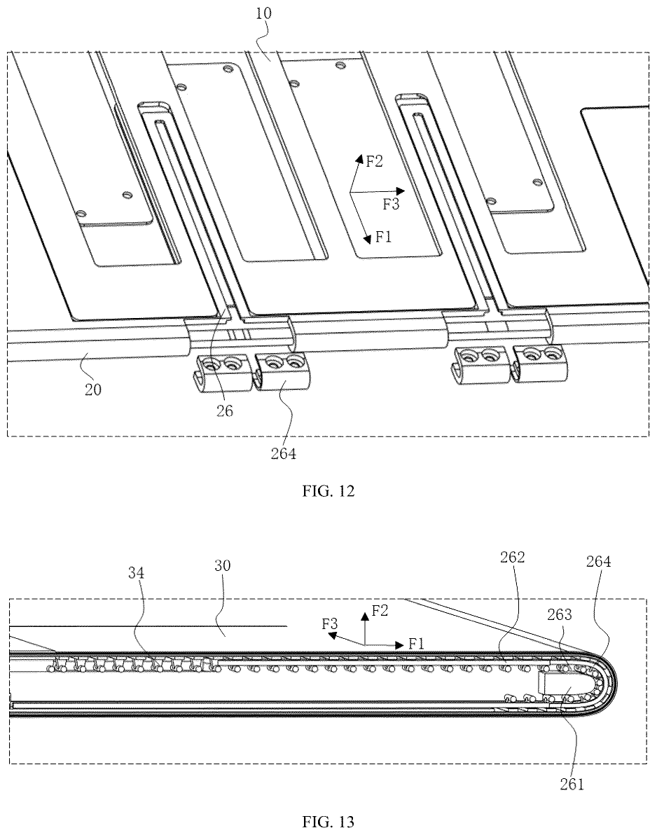

As shown in FIG. 12 to FIG. 13, in an optional embodiment, the intermediate rail 26 includes an elongated second inner guide post 261 and a U-shaped second outer guide post 262. The second inner guide post 261 extends in the first direction F1, and a U-shaped opening of the second outer guide post 262 faces the fixed middle frame 10 in the first direction F1. The second outer guide post 262 surrounds the second inner guide post 261, the second outer guide post 262 and the second inner guide post 261 are spaced, and a spacing between the second outer guide post 262 and the second inner guide post 261 forms a second U-shaped rail groove 263. The rail slider 323 may be clamped in the second U-shaped rail groove 263 and may slide along the second U-shaped rail groove 263.

As shown in FIG. 12 to FIG. 13, in an optional embodiment, the second outer guide post 262 located in a bending region of the second U-shaped rail groove 263 is manufactured separately and then assembled to the movable front housing 20 so as to form a closed intermediate rail 26. For example, two U-shaped structural members 264 may be manufactured separately, and then the structural members 264 are fixed to the bending region of the second U-shaped rail groove 263 of the movable front housing 20 by means of screw or other methods, so as to form a continuous and closed intermediate rail 26.

As shown in FIG. 1 to FIG. 13, in an optional embodiment, a distance between an intermediate rail 26 and an adjacent side rail 23 is less than or equal to 110 mm, and a distance between adjacent intermediate rails 26 is less than or equal to 110 mm. The distance between each of the intermediate rails 26 and an adjacent side rail 23 and the distance between adjacent intermediate rails 26 may be 95 mm, 100 mm, 105 mm, 108 mm, 110 mm, or the like.

A position of the fixed rear housing 40 in the second direction F2 corresponds to the fixed middle frame 10, and a position of the movable rear housing 50 in the second direction F2 corresponds to the movable front housing 20. The fixed rear housing 40 and the movable rear housing 50 are disposed on a side of the fixed middle frame 10 away from the display side. An overlapping region 42 is provided between the fixed rear housing 40 and the movable rear housing 50. A length of the overlapping region 42 is determined by the length of the scrolling region 32 when it is fully unfolded. For example, if the length of the scrolling region 32 when it is fully unfolded is X, the length of the overlapping region 42 is greater than X. Optionally, the length of the overlapping region 42 in the first direction F1 may be X+4 mm, X+5 mm, X+6 mm, X+7 mm, X+8 mm, or the like. This may ensure that when the scrolling region 32 is fully unfolded, a certain overlapping length is provided between the fixed rear housing 40 and the movable rear housing 50, and the fixed rear housing 40 may not be disconnected from the movable rear housing 50. A magnetic assembly 41 is provided on a side of the fixed rear housing 40 away from the display side. The movable rear housing 50 wraps around two sides of the display module in the first direction F1.

As shown in FIG. 1 to FIG. 13, in an optional embodiment, the structures in the above-mentioned embodiments may all be symmetrically disposed on two sides of the display module in the first direction F1, so as to form a display module structure that may be unfolded and scrolled on two sides. For example, the guide groove 11 and the movable front housing 20 are symmetrically provided on the other side of the fixed middle frame 10 in the first direction F1, the scrolling region 32 is also symmetrically provided on the other side of the middle region 31 in the first direction F1, and the movable rear housings 50 are provided on two opposite sides of the fixed rear housing 40 in the first direction F1. In the above-mentioned embodiments, various structures on the fixed middle frame 10, the movable front housing 20, and the flexible display screen 30 may all be symmetrically disposed on two sides of the display module in the first direction F1. Optionally, the structures in the above-mentioned embodiments may also be asymmetrically disposed on two sides of the display module, so as to form a display module structure that may be unfolded and scrolled on two sides. For example, the guide groove 11 and the movable front housing 20 are asymmetrically provided on the other side of the fixed middle frame 10 in the first direction F1, the scrolling region 32 is also asymmetrically provided on the other side of the middle region 31 in the first direction F1, and the movable rear housings 50 are asymmetrically provided on the two opposite sides of the fixed rear housing 40 in the first direction F1. In the above-mentioned embodiments, various structures on the fixed middle frame 10, the movable front housing 20, and the flexible display screen 30 may all be asymmetrically disposed on two sides of the display module in the first direction F1.

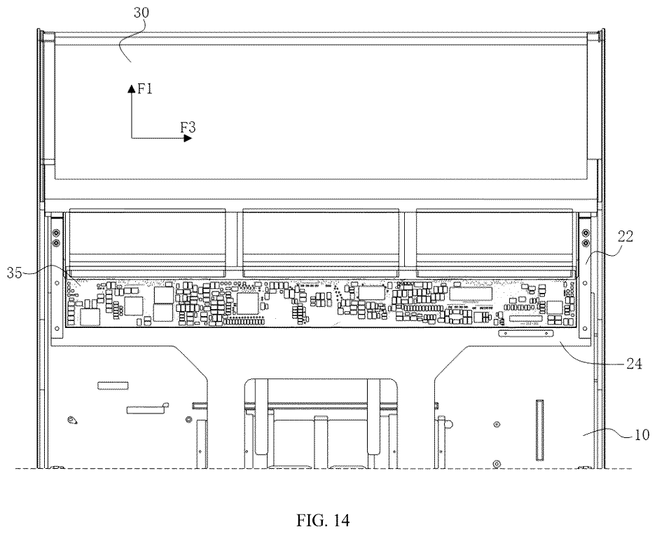

As shown in FIG. 14, in an optional embodiment, the flexible display screen 30 includes a circuit board region 35. The front housing push rods 22 on two sides of the movable front housing 20 are extended in the first direction F1, such that a projection of the circuit board region 35 in the second direction F2 falls between the front housing push rods 22 on two sides of the movable front housing 20. An end of the front housing push rod 22 close to the fixed middle frame 10 is connected to a connector 24, and the connector 24 is connected to the driving device. Optionally, the connector 24 may be a thin force-transmitting component such as a metal sheet or a plastic sheet. The driving device pushes the connector 24, the connector 24 pushes the front housing push rod 22, the front housing push rod 22 pushes the movable front housing 20, and the movable front housing 20 drives the flexible display screen 30 to scroll or unfold by means of the side rails 23 and the intermediate rails 26. Such arrangement may allow the circuit board region 35 to be protected by the front housing push rods 22 on two sides of the movable front housing 20, thereby preventing damage to the circuit board region 35.

After considering and practicing the present disclosure, those skilled in the art may easily conceive of other embodiments of the present disclosure. The present disclosure is intended to cover any modifications, uses, or adaptive changes of the present disclosure, and these modifications, uses, or adaptive changes follow the general principle of the present disclosure and include common knowledge or conventional technical means in the technical field that are not disclosed in the present disclosure. The present disclosure and the embodiments are merely regarded as exemplary, and the true scope and spirit of the present disclosure are indicated by the following claims.

It should be understood that the present disclosure is not limited to the precise structures described above and shown in the accompanying drawings, and various modifications and changes may be made without departing from the scope of the present disclosure. The scope of the present disclosure is only limited by the appended claims.

The above are only preferred embodiments of the present disclosure, and are not intended to limit the present disclosure. Any modifications, equivalent substitutions, improvements, etc. made within the spirit and principles of the present disclosure shall be included in the scope of protection of the present disclosure.

1. A display module, comprising:
a fixed middle frame, wherein a side of the fixed middle frame is provided with a guide groove;
a movable front housing disposed on the side of the fixed middle frame provided with the guide groove, wherein the movable front housing comprises a guide tongue piece matching with the guide groove to restrict a movement of the movable front housing relative to the fixed middle frame in a first direction;
a driving device configured to drive the movable front housing to move relative to the fixed middle frame in the first direction;
a flexible display screen comprising a middle region and a scrolling region located on a side of the middle region, wherein the middle region is located on surfaces of the fixed middle frame and the movable front housing close to a display side, and the scrolling region covers a surface of the movable front housing close to the display side and is bent to a surface of the movable front housing away from the display side;
wherein,
when the movable front housing moves relative to the fixed middle frame in the first direction, a state of the scrolling region switches between an unfolded state and a scrolled state;
a plurality of strip-shaped members are arranged at intervals in the first direction on a side of the scrolling region close to the movable front housing; and
the first direction is a length direction of the fixed middle frame.

2. The display module according to claim 1, wherein the guide groove is an elongated guide groove extending in the first direction; and
the guide groove comprises a hollowed-out region penetrating the guide groove in a
second direction, and the second direction is a direction perpendicular to a display surface.

3. The display module according to claim 2, wherein,
the hollowed-out region is located on a side of the guide groove away from the movable front housing; and
a projection area of the hollowed-out region in the second direction accounts for 0 to ¾ of a projection area of the guide groove in the second direction.

4. The display module according to claim 1, wherein,
a sidewall of the guide groove is provided with a sub-guide groove;
the sub-guide groove matches with the guide tongue piece to prevent a movement of the movable front housing relative to the fixed middle frame in a second direction; and
the second direction is a direction perpendicular to a display surface.

5. The display module according to claim 1, wherein a guide rail is provided on each of two sides of the fixed middle frame in the first direction, a guide slider is provided on the guide rail, and the guide slider is fixedly connected to the movable front housing.

6. The display module according to claim 1, wherein,
a plurality of support groups are provided on a side of the scrolling region close to the movable front housing;
each of the plurality of support groups comprises a plurality of supports arranged at intervals in the first direction; and
the plurality of supports are configured to support the flexible display screen, such that a spacing is provided between the flexible display screen and the movable front housing.

7. The display module according to claim 6, wherein,
the plurality of support groups comprises a first support group disposed on each of two opposite sides of the flexible display screen in a third direction;
a rail slider is provided at an end of a support in each of the first support groups close to the movable front housing; and
a U-shaped side rail is provided on each of two opposite sides of the movable front housing, a U-shaped opening of each side rail faces the fixed middle frame, and the rail slider is configured to slide along the side rail.

8. The display module according to claim 7, wherein,
the plurality of support groups further comprises second support groups disposed between the two first support groups;
a plurality of intermediate rails are provided between the side rails on two sides of the movable front housing, and the number of the plurality of intermediate rails corresponds to the number of the second support groups; and
each of the plurality of intermediate rails is a U-shaped rail, a U-shaped opening of the intermediate rail faces the fixed middle frame, and the rail slider is configured to slide along the intermediate rail.

9. The display module according to claim 7, wherein the side rail comprises an elongated first inner guide post and a U-shaped first outer guide post, the first outer guide post surrounds the first inner guide post, and a first U-shaped rail groove is formed between the first outer guide post and the first inner guide post.

10. The display module according to claim 9, wherein,
a front housing side cover is provided on each of two sides of the movable front housing; the first outer guide post is disposed on the front housing side cover; and
the first inner guide post is jointly formed by a first protrusion located on the front housing side cover and a second protrusion located on each of two sides of the movable front housing.

11. The display module according to claim 8, wherein the intermediate rail comprises an elongated second inner guide post and a U-shaped second outer guide post, the second outer guide post surrounds the second inner guide post, and a second U-shaped rail groove is formed between the second outer guide post and the second inner guide post.

12. The display module according to claim 11, wherein the second outer guide post located in a bending region of the second U-shaped rail groove is manufactured separately and then assembled to the movable front housing to form a closed intermediate rail.

13. The display module according to claim 8, wherein a distance between an intermediate rail and an adjacent side rail is less than or equal to 110 mm, and a distance between adjacent intermediate rails is less than or equal to 110 mm.

14. The display module according to claim 1, wherein,
the guide groove and the movable front housing are symmetrically provided on the other side of the fixed middle frame; and
the scrolling region is symmetrically provided on the other side of the middle region.

15. The display module according to claim 5, wherein,
a front housing push rod is provided on each of two sides of the movable front housing in the first direction, and an end of the front housing push rod close to the fixed middle frame is fixed with the guide slider;
the flexible display screen comprises a circuit board region, and a projection of the circuit board region in the second direction falls between the front housing push rods on two sides of the movable front housing;
an end of the front housing push rod close to the fixed middle frame is connected to a connector, and the connector is connected to the driving device; and
the second direction is the direction perpendicular to the display surface.

16. A display device, comprising the display module according to any one of claim 1.
